(19) United States
(12) Patent Application Publication
(10) Pub. No.: US 2025/0078881 A1
(43) Pub. Date: Mar. 6, 2025

(54) METHOD AND APPARATUS FOR OPERATING IN-MEMORY COMPUTING ARCHITECTURE APPLIED TO NEURAL NETWORK AND DEVICE

(71) Applicant: Peking University, Haidian District, Beijing (CN)

(72) Inventors: Peng HUANG, Haidian District, Beijing (CN); Lixia HAN, Haidian District, Beijing (CN); Xiaoyan LIU, Haidian District, Beijing (CN); Jinfeng KANG, Haidian District, Beijing (CN)

(73) Assignee: Peking University, Haidian District, Beijing (CN)

(21) Appl. No.: 18/288,858

(22) PCT Filed: Jun. 17, 2022
(86) PCT No.: PCT/CN2022/099347

§ 371 Date: Oct. 30, 2023

(51) Int. Cl. G11C 7/10; G06F 17/16

(52) U.S. Cl. CPC G11C 7/1066; G06F 17/16; G11C 7/1093

(57) ABSTRACT

The present disclosure provides a method and an apparatus for operating an in-memory computing architecture applied to a neural network and a device, the method includes: generating a mono-pulse input signal based on discrete time coding; inputting the mono-pulse input signal into a memory array of the in-memory computing architecture to generate a bit line current signal corresponding to the memory array; and controlling a neuron circuit of the in-memory computing architecture to output a mono-pulse output signal based on discrete time coding according to the bit line current signal, wherein the mono-pulse output signal is configured as a mono-pulse input signal of a memory array of the next layer of neural network in the next in-memory computing cycle.

### TECHNICAL FIELD

The present disclosure relates to fields of semiconductor device technology and integrated circuit technology, and in particular, to a method and an apparatus for operating an in-memory computing architecture applied to neural networks and devices.

### BACKGROUND

A data-intensive deep learning model and rapidly growing unstructured data put forward higher requirements for energy efficiency and area overhead of processors. However, due to the bottleneck of data movement between arithmetic logic units and memory, energy consumption traditional processors based on Von Neumann architecture is difficult to reduce and not suitable for deployment on terminal devices with limited energy supply. In-memory computing architecture may perform in situ parallel computing efficiently in the memory, so as to greatly speed up matrix-vector multiplication calculation and avoid energy consumption caused by data movement.

However, in the existing in-memory computing architectures based on mixed-signal input coding, huge energy consumption of analog-to-digital converters limits an improvement of energy efficiency. Although in-memory computing architectures based on spike rate input coding uses integrate-and-fire circuits to avoid energy-intensive analog-to-digital converters, the energy consumption caused by a large number of input spike is still huge.

### SUMMARY

In order to solve the technical problem that the existing in-memory computing architecture may not effectively improve energy efficiency, the present disclosure provides a method and an apparatus for operating an in-memory computing architecture applied to neural networks and devices.

The first aspect of the present disclosure provides a method for operating an in-memory computing architecture applied to a neural network, including: generating a mono-pulse input signal based on discrete time coding; inputting the mono-pulse input signal into a memory array of the in-memory computing architecture to generate a bit line current signal corresponding to the memory array; and controlling a neuron circuit of the in-memory computing architecture to output a mono-pulse output signal based on discrete time coding according to the bit line current signal, wherein the mono-pulse output signal is configured as a mono-pulse input signal of a memory array of the next layer of neural network in the next in-memory computing cycle.

According to embodiments of the present disclosure, generating a mono-pulse signal based on discrete time coding includes: quantizing neural network input vector signal and generating a corresponding quantized input signal; and coding the quantized input signal according to a preset discrete delay time coding rule to generate the mono-pulse input signal based on discrete time coding; wherein the preset discrete delay time coding rule is a rule for coding quantized input of neural networks into the mono-pulse input signal according to a delay time between a start time of an enable signal corresponding to the in-memory computing cycle and an arrival time of the mono-pulse input signal, wherein the length of the delay time is the size of the quantized input signal.

According to embodiments of the present disclosure, before inputting the mono-pulse input signal into a memory array of the in-memory computing architecture to generate a bit line current signal corresponding to the memory array, the method further includes: mapping a weight matrix corresponding to neural network input vector signal to each memory unit of the memory array, including: mapping the weight matrix to conductance values in two adjacent columns of the memory array representing positive and negative respectively according to the symbol of weights; and mapping a weight difference between two adjacent columns to conductance values of two adjacent columns representing positive and negative respectively of the memory array according to the symbol of the weight difference, wherein the weight difference is a difference between a sum of weights of an adjacent negative column and a sum of weights of an adjacent positive column.

According to embodiments of the present disclosure, inputting the mono-pulse input signal into a memory array of the in-memory computing architecture to generate a bit line current signal corresponding to the memory array includes: inputting the mono-pulse input signal into the memory array of the in-memory computing architecture; and controlling the memory array to complete matrix-vector multiplication based on the input mono-pulse input signal to generate the bit line current signal.

According to embodiments of the present disclosure, before controlling a neuron circuit of the in-memory computing architecture to output a mono-pulse output signal based on discrete time coding according to the bit line current signal, the method further includes: performing a selection processing on the bit line current signal by a multiplexer of the in-memory computing architecture corresponding to the memory array.

According to embodiments of the present disclosure, controlling a neuron circuit of the in-memory computing architecture output a mono-pulse output signal based on discrete time coding according to the bit line current signal includes: controlling an on-off state of a first switching transistor and a second switching transistor of the neuron circuit in response to the bit line current signal, so that the neuron circuit outputs the mono-pulse output signal in response to the on-off state.

According to embodiments of the present disclosure, before controlling an on-off state of a first switching transistor and a second switching transistor of the neuron circuit in response to the bit line current signal so that the neuron circuit outputs the mono-pulse output signal in response to the on-off state, the method further includes: controlling an on-off state to satisfy that the first switching transistor is on and the second switching transistor is off, and implementing a pre-charging capacitor voltage of the neuron circuit in response to the on-off state.

According to embodiments of the present disclosure, controlling an on-off state of a first switching transistor and a second switching transistor of the neuron circuit in response to the bit line current signal so that the neuron circuit outputs the mono-pulse output signal in response to the on-off state includes: controlling an on-off state to satisfy that the first switching transistor and the second switching transistor are both off, and enabling the neuron circuit to generate the first capacitor voltage according to the bit line current signal and the pre-charging capacitor voltage in response to the on-off state and the bit line current signal; and controlling an on-off state to satisfy that the first switching transistor is off and the second switching transistor is on, and coding and outputting the first capacitor voltage as the mono-pulse output signal with a discrete delay time.

The second aspect of the present disclosure provides an apparatus for operating an in-memory computing architecture applied to a neural network, including: an input signal generation module configured to generate a mono-pulse input signal based on discrete time coding; a bit line signal generation module configured to input the mono-pulse input signal into a memory array of the in-memory computing architecture to generate a bit line current signal corresponding to the memory array; and a control output module configured to control a neuron circuit of the in-memory computing architecture to output a mono-pulse output signal based on discrete time coding according to the bit line current signal, wherein the mono-pulse output signal is configured as a mono-pulse input signal of a memory array of the next layer of neural network in the next in-memory computing cycle.

The third aspect of the present disclosure provides an electronic device, including: one or more processors; and a memory for storing one or more programs, wherein the one or more programs, when executed by the one or more processors, causes the one or more processors to implement the method for operating an in-memory computing architecture applied to a neural network described above.

The fourth aspect of the present disclosure further provides a computer-readable storage medium having executable instructions therein, wherein the instructions, when executed by a processor, cause the processor to implement the method for operating an in-memory computing architecture applied to a neural network described above.

The fifth aspect of the present disclosure further provides a computer program product containing a computer program, wherein the computer program, when executed by a processor, implements the method for operating an in-memory computing architecture applied to a neural network described above.

The present disclosure provides a method and an apparatus for operating an in-memory computing architecture applied to a neural network and a device, wherein the method includes: generating a mono-pulse input signal based on discrete time coding; inputting the mono-pulse input signal into a memory array of the in-memory computing architecture to generate a bit line current signal corresponding to the memory array; and controlling a neuron circuit of the in-memory computing architecture output a mono-pulse output signal based on discrete time coding according to the bit line current signal, wherein the mono-pulse output signal is used as a mono-pulse input signal of a memory array of a next layer of neural network in a next in-memory computing cycle. Therefore, the mono-pulse input in the in-memory computing architecture may be implemented through a mono-pulse input signal based on discrete time coding, thus greatly reducing the number of input pulses and the dynamic power consumption of the memory array and the neural circuit.

### BRIEF DESCRIPTION OF THE DRAWINGS

FIG. 1 schematically shows an application scenario diagram of a method and an apparatus for operating an in-memory computing architecture applied to a neural network, a device, a medium and a program product according to embodiments of the present disclosure.

FIG. 2 schematically shows a flow chart of a method for operating an in-memory computing architecture applied to a neural network according to an embodiment of the present disclosure.

FIG. 3A schematically shows a corresponding matrix-vector multiplication calculation diagram of an in-memory computing architecture applied to a neural network according to an embodiment of the present disclosure.

FIG. 3B schematically shows a structural composition and a technical schematic diagram corresponding to the in-memory computing architecture applied to a neural network in FIG. 3A according to an embodiment of the present disclosure.

FIG. 3C schematically shows a circuit structure composition diagram of a neuron circuit of an in-memory computing architecture applied to a neural network according to an embodiment of the present disclosure.

FIG. 4A schematically shows a node waveform diagram of a neuron circuit of an in-memory computing architecture applied to a neural network according to an embodiment of the present disclosure.

FIG. 4B schematically shows a simulation diagram of a relationship between a discrete delay time Tout of a mono-pulse input signal and a target vector-matrix multiplication result λG·X·T_{code} according to an embodiment of the present disclosure.

FIG. 5 schematically shows a block diagram of an apparatus for operating an in-memory computing architecture applied to a neural network according to an embodiment of the present disclosure.

FIG. 6 schematically shows a block diagram of an electronic device suitable for implementing a method for operating an in-memory computing architecture applied to a neural network according to an embodiment of the present disclosure.

### DETAILED DESCRIPTION OF EMBODIMENTS

In order to make objectives, technical solutions and advantages of the present disclosure more apparent and understandable, the present disclosure is further described in detail below in combination with specific embodiments and with reference to the accompanying drawings.

It should be noted that the implementation methods not shown or described in the accompanying drawings or the text of the specification are all in forms known to those of ordinary skill in the art and are not described in detail. In addition, the above-mentioned definitions of various elements and methods are not limited to various specific structures, shapes or methods mentioned in the embodiments, which may be simply changed or replaced by those of ordinary skill in the art.

It should also be noted that directional terms mentioned in the embodiments, such as “up”, “down”, “front”, “back”, “left”, “right”, etc., are only the directions referring to the accompanying drawings and are not intended to limit the scope of protection of the present disclosure. Throughout the accompanying drawings, the same elements are represented by the same or similar reference signs. Conventional structures or constructions will be omitted when they may obscure the understanding of the present disclosure.

In addition, shapes and sizes of the respective components in the figures do not reflect true sizes and proportions, but merely illustrate contents of embodiments of the present disclosure. Moreover, in the claims, any reference signs placed between parentheses should not be construed as limiting the claims.

Furthermore, the word “including” does not exclude the presence of elements or steps not listed in the claims. The word “a” or “an” preceding an element does not exclude the presence of a plurality of such elements.

The use of ordinal numbers such as “first”, “second”, “third”, etc. in the specification and claims to modify a corresponding element do not mean that the element has any ordinal number, nor does it represent the ordering of one element relative to another element or the ordering of manufacturing methods. The use of such ordinal numbers is only used to clearly distinguish an element having a certain name and another element having the same name.

Those skilled in the art will appreciate that the modules in the device in an embodiment may be adaptively changed and arranged in one or more devices different from the embodiment. The modules or units or components in the embodiments may be combined into one module or unit or component, and they may also be divided into a plurality of sub modules or sub units or sub components. Except that at least some of such features and/or processes or units are mutually exclusive, any combination may be used to combine all the features disclosed in the specification (including accompanying claims, abstract and drawings) and all the processes or units of any method or device so disclosed. Unless otherwise expressly stated, each feature disclosed in the specification (including accompanying claims, abstract and drawings) may be replaced by a substitute feature serving the same, equivalent or similar purpose. Moreover, in a unit claim that enumerates several devices, several of these devices may be embodied by the same hardware item.

Similarly, it should be understood that, in order to simplify the present disclosure and help understand one or more of the various disclosed aspects, in the above description of exemplary embodiments of the present disclosure, various features of the present disclosure are sometimes grouped together into a single embodiment, figure, or description thereof. However, the disclosed method should not be construed to reflect the intent that the present disclosure is directed to more features than are expressly recited in each claim. More precisely, as the following claims reflect, disclosed aspects lie in less than all features of a single foregoing disclosed embodiment. Therefore, the claims following the specific embodiment are hereby explicitly incorporated into the specific embodiment, wherein each claim itself is a separate embodiment of the present disclosure.

In order to solve the technical problem that the existing in-memory computing architecture may not effectively improve the energy efficiency, the present disclosure provides a method and an apparatus for operating an in-memory computing architecture applied to a neural network, and a device.

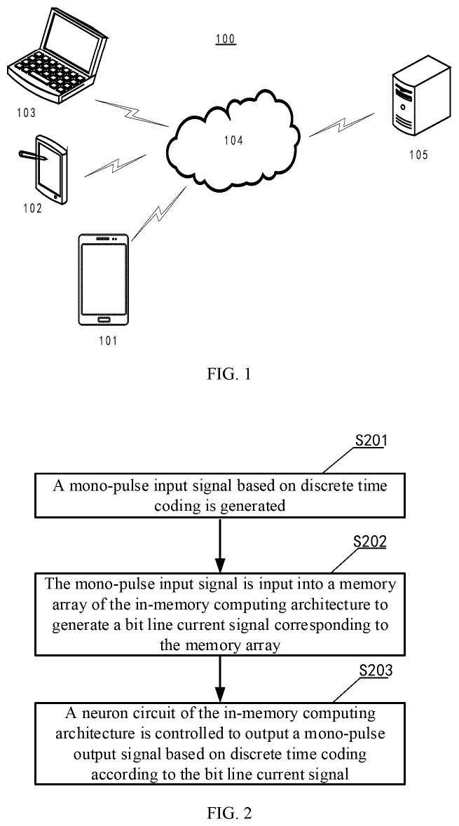

FIG. 1 schematically shows an application scenario diagram of a method for operating an in-memory computing architecture applied to a neural network according to an embodiment of the present disclosure.

As shown in FIG. 1, an application scenario 100 according to the embodiment may include terminal devices 101, 102, 103, a network 104, and a server 105. The network 104 is a medium for providing a communication link between the terminal devices 101, 102, 103 and the server 105. The network 104 may include various connection types, such as wired, wireless communication links, optical fiber cables, and the like.

The user may use the terminal devices 101, 102, 103 to interact with the server 105 through the network 104 to receive or send a message and the like. The terminal devices 101, 102 and 103 may be installed with various communication client applications, such as a shopping application, a web browser application, a search application, an instant messaging tool, an email client, a social platform software, and the like (for example only).

The terminal devices 101, 102, 103 may be various electronic devices having a display screen and supporting web browsing, including but not limited to a smart phone, a tablet computer, a laptop computer, a desktop computer, and the like.

The server 105 may be a server that provides various services, such as a background management server (for example only) that provides a support for a website browsed by a user using the terminal devices 101, 102, 103. The background management server may analyze and process a received user request and other data, and feed back a processing result (e.g., web page, information or data acquired or generated according to the user request) to the terminal devices.

It should be noted that the method for operating an in-memory computing architecture applied to a neural network provided in embodiments of the present disclosure may generally be performed by the server 105. Accordingly, the apparatus for operating an in-memory computing architecture applied to a neural network provided by embodiments of the present disclosure may generally be provided in the server 105. The method for operating an in-memory computing architecture applied to a neural network provided by embodiments of the present disclosure may also be performed by a server or server cluster different from the server 105 and capable of communicating with the terminal devices 101, 102, 103 and/or the server 105. Accordingly, the apparatus for operating an in-memory computing architecture applied to a neural network provided by embodiments of the present disclosure may also be provided in a server or server cluster different from the server 105 and capable of communicating with the terminal devices 101, 102, 103 and/or the server 105.

It should be understood that the number of terminal devices, network and server in FIG. 1 is only schematic. According to implementation needs, any number of terminal devices, network and server may be provided.

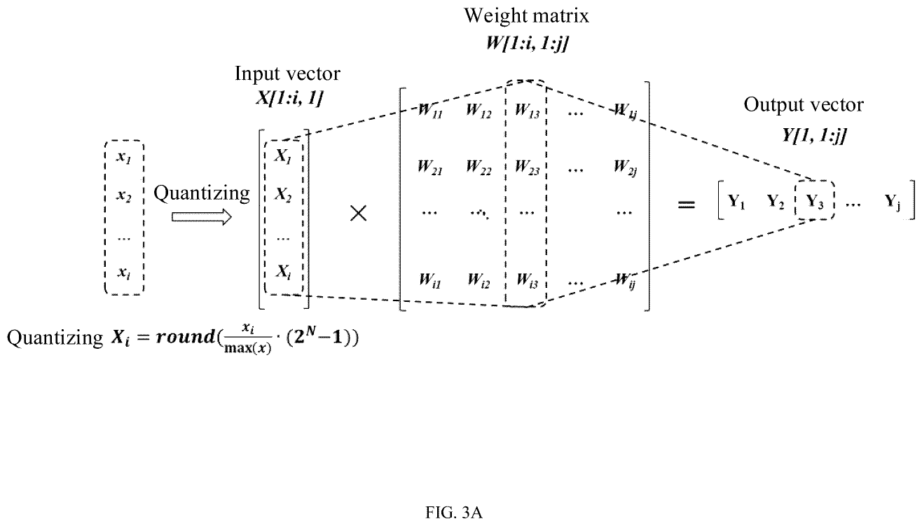

Based on the scenario described in FIG. 1, the method for operating an in-memory computing architecture applied to a neural network of embodiments of the present disclosure will be described in detail through FIG. 2 to FIG. 6.

FIG. 2 schematically shows a flow chart of a method for operating an in-memory computing architecture applied to a neural network according to an embodiment of the present disclosure.

As shown in FIG. 2, the method for operating an in-memory computing architecture applied to a neural network in the embodiment includes operation S201 to operation S203.

In operation S201, a mono-pulse input signal based on discrete time coding is generated.

In operation S202, the mono-pulse input signal is input into a memory array of the in-memory computing architecture to generate a bit line current signal corresponding to the memory array.

In operation S203, a neuron circuit of the in-memory computing architecture is controlled to output a mono-pulse output signal based on discrete time coding according to the bit line current signal, wherein the mono-pulse output signal is configured as a mono-pulse input signal of a memory array of a next layer of neural network in a next in-memory computing cycle.

The mono-pulse input signal based on discrete time coding is obtained by performing the discrete time coding on the signal input to the memory array of the in-memory computing architecture through the discrete-time coding solution, so that the mono-pulse signal with discrete a delay time characteristic may represent a size of the input signal. The discrete delay time characteristic may be understood as: the pulse signal is encoded by using the delay time between the arrival time of the pulse and the start time of the enable signal of the pulse response, so that the larger input value of the memory array of the in-memory computing architecture may be encoded into a pulse signal with a longer delay time, and the smaller input value may be encoded into a pulse signal with a shorter delay time. Specifically, an input strength may be expressed according to the leakage time of the neuron to the charge. The longer the delay time is, the shorter the leakage time is, the more charge the neuron retains, and the larger the input value of the corresponding memory array is. Therefore, an operation for the memory array may be implemented, and a corresponding bit line current signal of a storage array may be generated.

The in-memory computing architecture includes a memory array and a matched operating circuit module. The memory array includes a nonvolatile memory array (NVM array for short) structure, which may be used to perform a processing procedure of matrix-vector multiplication computation on an input signal and generate a corresponding bit line current signal. The bit line current signal is a current signal generated by the memory array in response to the above-mentioned mono-pulse input signal corresponding to the input value, and is output through the bit line of the memory array. The bit line current signal may be used to generate the output signal corresponding to the input value, i.e., the mono-pulse output signal.

In addition, the in-memory computing architecture may further include a neuron circuit adapted to the memory array, and the neuron circuit may convert the bit line current signal to generate a corresponding mono-pulse output signal. The discrete time signal characteristics of the mono-pulse output signal and the input mono-pulse input signal may be kept consistent, thus implementing the discrete time coding of the pulse signal on the whole, while ensuring the discrete time characteristic of the output signal, thereby reducing the number of input pulses.

For the in-memory computing architecture based on neural network, a plurality of in-memory computing cycles are involved in implementing the corresponding in-memory computing process, and each in-memory computing cycle may correspond to a data processing process of a neural network layer of the neural network. Each mono-pulse output signal may be used as an input signal of a memory array of the next layer of neural network in the next in-memory computing cycle, and since the mono-pulse output signal has the above-mentioned discrete time signal characteristic, the memory array of the next layer of neural network corresponding to the mono-pulse output signal may output the next mono-pulse output signal in the next memory computing cycle, and the above steps are repeated until the progress of memory computing processing is completed, and a result is an output.

Therefore, compared with the way of encoding the array input value through a plurality of pulse signals in the prior art, the present disclosure encodes the input signal into a mono-pulse signal with the discrete delay time characteristic, so that only a mono-pulse signal is required to implement the operation of the memory array, and generate a corresponding bit line current signal of a storage array. Hence, the number of input pulses may be greatly reduced to greatly reduce the dynamic power consumption of in-memory computing architectures such as memory arrays and corresponding neural circuits. At the same time, by quantifying the delay time into discrete delay time to replace the analog delay time, the present disclosure is well-compatible with digital circuits.

The above-mentioned in-memory computing structure of embodiments of the present disclosure may implement obtaining a pulse neural network of time coding by direct training, such as TTFS coding (i.e., time-to-first spike) solution, so that each neuron may emit at most one pulse in the corresponding in-memory computing process; the above-mentioned in-memory computing structure may also implement obtaining a pulse neural network of time coding by deep neural network conversion. It may be seen that the above-mentioned method for embodiments of the present disclosure provides a neural network in-memory computing implementation solution based on time coding, which may implement the mono-pulse input in the in-memory computing architecture through a mono-pulse input signal based on discrete time coding, thus greatly reducing the number of input pulses the dynamic power consumption of the memory array and the neural circuit.

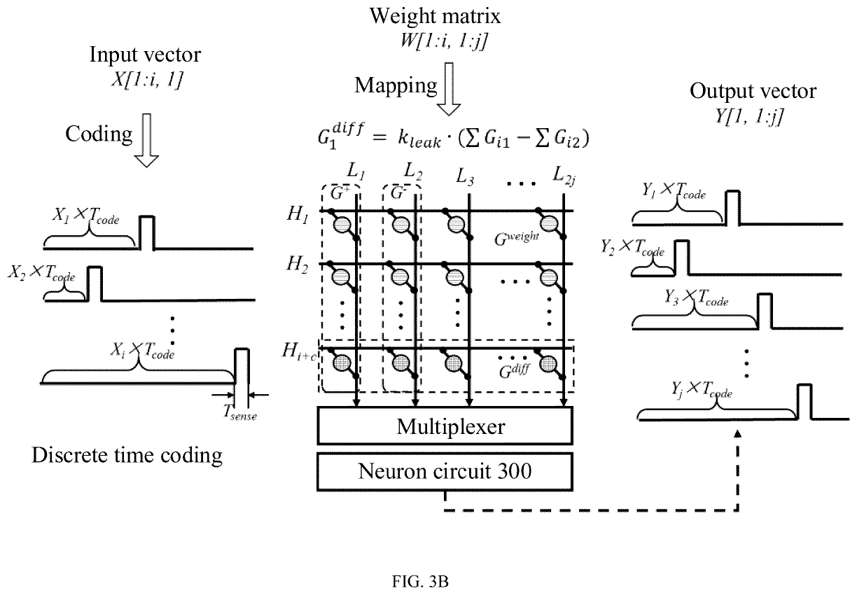

As shown in FIG. 2 to FIG. 3C, according to embodiments of the present disclosure, in the generating a mono-pulse signal of discrete time coding of operation S201, the method includes:
quantizing neural network input vector signal and generating a corresponding quantized input signal; and
coding the quantized input signal according to a preset discrete delay time coding rule to generate a mono-pulse input signal based on discrete time coding;
wherein the preset discrete delay time coding rule is a rule for coding a mono-pulse into the mono-pulse input signal according to a delay time between a start time of an enable signal corresponding to the in-memory calculation cycle and an arrival time of the mono-pulse of the mono-pulse input signal in response to the enable signal, wherein, a length of the delay time is a size of the quantized input signal.

The schematic diagram of matrix-vector multiplication calculation based on discrete time coding shown in FIG. 3A to FIG. 3B may better reflect the above-mentioned technical principle of discrete time coding for pulse signals in embodiments of the present disclosure. The extracted neural network input vector signal may be a vector signal based on an image pixel feature extracted by image recognition technology. Quantizing the corresponding input vector x [1:i, 1] (i is a positive integer greater than 0) of these neural network input vector signals may generate corresponding quantized input signals. Specifically, the quantized input signal may be represented as the input vector X [1:i, 1] shown in FIG. 3A, which satisfies:

$${X}_{i} = round ( \frac{{x}_{i}}{max ( x )} \cdot ( {2}^{N} - 1 ) ) \qquad ( 1 )$$

where Xᵢ is an element in the discrete N bit input vector X [1:i, 1] which is quantized from the corresponding input vector x [1:i, 1], i is a positive integer greater than 0, N is a positive integer greater than 0, and N represents the accuracy of the input quantization.

Therefore, the discrete time coding may specifically be quantizing the input vector x [1:i, 1] into the N bit input vector X [1:i, 1], and then encoding the N bit input vector X [1:i, 1] into a mono-pulse signal with a delay time of X·T_{code}. FIG. 3B shows the matrix-vector multiplication operation based on discrete time coding, the total coding time of the discrete time coding solution is (2N−1)·T_{code}+Tₛₑₙₛₑ, where N is quantization input precision, T_{code} is unit delay time, and Tₛₑₙₛₑ is a fixed pulse width of a pulse signal.

In an in-memory computing cycle initiated in the in-memory calculation process, the mono-pulse input signal may be enabled by controlling the generated enable signal. The start time of the enable signal may be understood as the generation time of the enable signal, and accordingly, the arrival time of the mono-pulse may be understood as the time at which the mono-pulse arrives at the memory array in response to the enable signal. The time difference between the two is the above-mentioned delay time. The corresponding mono-pulse input signal may be generated by encoding the mono-pulse through the delay time. The length of the delay time may be understood as the size of the quantized input signal, which may be used to feedback the size of the input value corresponding to the quantized input signal, and the longer the delay time, the larger the input value.

As shown in FIG. 2 to FIG. 3C, according to embodiments of the present disclosure, before inputting the mono-pulse input signal into a memory array of the in-memory computing architecture to generate a bit line current signal corresponding to the memory array of operation S202, the method further includes:
mapping a weight matrix corresponding to neural network input vector signal to each memory unit of the memory array, including: mapping the weight matrix to conductance values of two adjacent columns representing positive and negative respectively of the memory array respectively according to the symbol of weights; and mapping a weight difference between two adjacent columns to conductance values of two adjacent columns representing positive and negative respectively of the memory array according to a weight difference symbol, wherein the weight difference is a difference between a sum of weights of an adjacent negative column and a sum of weights of an adjacent positive column.

As shown in FIG. 3A and FIG. 3B, the weight matrix corresponding to the above-mentioned neural network input vector signal x [1:i, 1] may be W [1:i, 1:j], the weight values in the weight matrix are mapped to the conductance values (G⁺ and G⁻) of two adjacent columns of memory units in the memory array according to the weight symbol. The weight symbol may be the symbol of the weight value, if the weight value is positive, the symbol is positive, and vice versa. The memory array may be a non-volatile memory array, which may specifically have (i+c)×2j memory units, which are divided into Hᵢ-H_{i+c}, a total of i+c rows, and L₁−L₂ⱼ, a total of 2j columns. Specifically, the weight matrix W [1:i, 1:j] is mapped to the conductance values (G⁺ and G⁻) of the two adjacent memory units of the memory array according to the weight symbol. If the weight value Wᵢⱼ is positive, the weight value Wᵢⱼ is mapped to the positive conductance (G⁺) column. If the weight value Wᵢⱼ is negative, the weight value Wᵢⱼ is mapped to the negative conductance (G⁻) column. For example, if the weight values of W₁₁, W₂₁ . . . Wᵢ₁ in the weight matrix are one-to-one mapped to the memory units in rows H₁-Hᵢ of column L₁ or column L₂ according to the weight symbol, if Wᵢ₁ is positive, Wᵢ₁ is mapped to column L₁, and if Wᵢ₁ is negative, Wᵢ₁ is mapped to column L₂. Then the weight values of W₁₂, W₂₂ . . . Wᵢ₂ are one-to-one mapped to the memory units in rows H₁-Hᵢ of column L₃ or column L₄ according to the weight symbol. The adjacent columns are columns L₁ and L₂, and the next adjacent columns are columns L₃ and L₄. The conductance of the weight mapping of the original neural network algorithm is represented by G^{weight}.

In addition, a difference G^{diff}=kₗₑₐₖ(ΣG⁻−ΣG⁺) between the weight sums of two adjacent columns also needs to be mapped to the adjacent columns of the memory array according to the symbol of the weight difference, where kₗₑₐₖ is a leakage coefficient of a known neuron model. The difference between the weight sums of the two adjacent columns is mapped corresponding to the corresponding adjacent columns of rows Hᵢ₊₁-H_{i+c} of the memory array. For example, after completing the above-mentioned mapping the weight values of W₁₁, W₂₁ . . . Wᵢ₁ in the weight matrix one by one to the memory units in rows H₁-Hᵢ of column L₁ or column L₂ according to the weight symbol, and correspondingly mapping the weight values of W₁₂, W₂₂ . . . Wᵢ₂ one by one to the memory units in rows H₁-Hᵢ of column L₃ or column L₄ according to the weight symbol, the difference of the weight sums is correspondingly mapped to the memory units in rows Hᵢ₊₁-H_{i+c} of column L₁ or column L₂ and the memory units in rows Hᵢ₊₁-H_{i+c} of column L₃ or column L₄.

The difference of weight sums Gᵢ^{diff} is a difference conductance of the weight sums of two adjacent positive and negative columns, which satisfies:

$${G}_{j}^{diff} = {k}_{leak} \cdot ( {\sum }_{i} {G}_{ij} - {\sum }_{i} {G}_{i , j + 1} ) \qquad ( 2 )$$

where kₗₑₐₖ is the leakage coefficient of the known neuron model; the neuron model corresponds to the neural network of the above-mentioned in-memory computing architecture.

As shown in FIG. 2 to FIG. 3C, according to embodiments of the present disclosure, during inputting the mono-pulse input signal into a memory array of the in-memory computing architecture to generate a bit line current signal corresponding to the memory array of operation S202, the method further includes:
inputting the mono-pulse input signal into the memory array of the in-memory computing architecture; and
controlling the memory array that completes the weight matrix mapping to perform a multiplication and accumulation operation based on the input mono-pulse input signal to generate the bit line current signal.

After completing the above-mentioned mapping of the weight difference, the discrete time coded mono-pulse input signal may be applied to a corresponding operation line of the memory array of the memory computing architecture, such as a word line, to complete a response to the input value of the memory array. Based on the matrix-vector multiplication calculation schematic diagram shown in FIG. 3A, the memory array is controlled to complete the multiplication and accumulation process for the input mono-pulse input signal, and output a response current on the bit line of the array as the bit line current signal.

As shown in FIG. 2 to FIG. 3C, according to embodiments of the present disclosure, before controlling a neuron circuit of the in-memory computing architecture output a mono-pulse output signal based on discrete time coding according to the bit line current signal of operation S203, the method further includes:
selecting the bit line current signal by a multiplexer of the in-memory computing architecture corresponding to the memory array.

As shown in FIG. 3A, before the bit line current signal is input into the neuron circuit, for some special cases, such as the case of a plurality of neuron circuits, the bit line current signal may be selected through the multiplexer provided between the neuron circuit and the memory array to determine the final input neuron circuit of the bit line current signal. The multiplexer may be used as an alternative technology to adapt to a corresponding relationship between different memory arrays and neural circuits.

As shown in FIG. 2 to FIG. 3C, according to embodiments of the present disclosure, in the controlling a neuron circuit of the in-memory computing architecture output a mono-pulse output signal based on discrete time coding according to the bit line current signal of operation S203, the method includes:
controlling an on-off state of a first switching transistor and a second switching transistor of the neuron circuit in response to the bit line current signal, so that the neuron circuit outputs the mono-pulse output signal in response to the on-off state.

According to the technical principle of the above-mentioned discrete time coding, the control of neuron circuit requires a leaky integrate-and-fire circuit to integrate and convert the bit line current signal into a mono-pulse output signal with discrete delay time. By controlling the neuron circuit, a charge current corresponding to the positive weight value and a discharge current corresponding to the negative weight value in the memory array may be integrated simultaneously to obtain a capacitor voltage. Then, based on the capacitor voltage, the neuron circuit is further controlled to convert a voltage difference between the capacitor voltage and a threshold voltage into a mono-pulse output signal with discrete delay time. In addition, the neuron circuit also needs to keep an array read voltage constant under a large capacitor voltage range.

Therefore, the structure of a neuron circuit 300 is shown in FIG. 3C, and the neuron circuit 300 mainly includes a charging end 301, a discharging end 302, an operational amplifier 303, a comparator 304, a positive current mirror 305, a negative current mirror 306, an operational amplifier 307, and an output pulse memory 308, and the like. In addition, the neuron circuit 300 further includes a first switching transistor S1, a second switching transistor S2, a capacitor C, a resistor R, a constant current source CS, and a pre-charge resistor Rₚᵣₑ and the like. The charging end 301 and the discharging end 302 are used to connect the above-mentioned memory array, for an introduction of the bit line current signal of the weight array to the neuron circuit.

Therefore, the neuron circuit of the embodiment of the present disclosure has following functions: the integration of the bit line current and the leakage of the capacitor voltage described above are completed through the capacitor C and the resistor R. The positive and negative bit line voltages of the memory array of the in-memory computing architecture are respectively controlled by the operational amplifier 303 and the operational amplifier 307 to be independent of the voltage value of the neuron circuit capacitor C. In addition, the bit line current signals corresponding to the positive and negative weights are input into the neuron circuit through the charging terminal 301 and the discharging terminal 302 to charge and discharge the capacitor C simultaneously. The bit line current signal corresponding to the positive weight charges the capacitor C through the positive current mirror 305, while the bit line current signal corresponding to the negative weight discharges the capacitor through the negative current mirror 306 composed of two current mirror circuits. Secondly, the pre-charge resistor Rₚᵣₑ is used for pre-charging the capacitor C to make the capacitor reach a pre-charge voltage. Specifically, before the bit line current signal is connected to the neuron circuit, the capacitor C is pre-charged so that the capacitor C stores enough initial electrons to be discharged by the column current corresponding to the negative weight. Furthermore, after the input pulse is completed, the constant current source CS may discharge the capacitor C through the second switching transistor S2. The size of the constant current source CS may be controlled to control output precision of the mono-pulse output signal based on discrete delay time coding. In addition, when the capacitor voltage of capacitor C leaks to the threshold voltage Vₜₕ of the voltage comparator 304, the output pulse is triggered as the above-mentioned mono-pulse output signal. The capacitor C is connected to the comparator 304. When the capacitor voltage of the capacitor is less than the threshold voltage Vₜₕ and a rising edge of the clock is reached, the neuron circuit 300 will trigger an output pulse as the above-mentioned mono-pulse output signal. The output pulse may be temporarily stored in the register 308.

Therefore, as shown in FIG. 3C, the capacitor C and the resistor R of the neuron circuit 300 complete the integration and leakage functions respectively. The operational amplifiers 303 and 307 may clamp a bit line operating voltage of the memory array to a fixed value. The column current corresponding to the positive weight charges capacitor C through the positive current mirror 305, and the column current corresponding to the negative weight discharges capacitor C through the negative current mirror 306 composed of two current mirror circuits. In addition, a pre-charge resistor Rₚᵣₑ and a first switching transistor S1 are connected to the capacitor C, so that the capacitor C stores enough initial electrons to be discharged by the column current corresponding to the negative weight. The capacitor C is further connected with a constant current source CS and a voltage comparator 304 through the second switching transistor S2. When the capacitor voltage of the capacitor C is less than the threshold voltage Vₜₕ of the voltage comparator 304 and the rising edge of the clock is reached, the neuron circuit 300 will trigger an output pulse, and the output pulse is temporarily stored in the register 308. Therefore, the neuron circuit 300 may control the accuracy of the mono-pulse output signal based on discrete delay time coding by adjusting the constant current source CS.

The completion of the neural network in-memory calculation based on discrete time coding is implemented for the operation of the neuron circuit, which specifically involves:
pre-charging the capacitor, matrix-vector multiplication calculation processing and vector-matrix multiplication result coding.

A leaky integrate-and-fire model (LIF neuron model for short) is a model that describes a dynamic behavior of a neuron. The LIF neuron model may obtain a membrane voltage by integrating a stimulated current. When the membrane voltage reaches the threshold voltage, the neuron triggers the pulse and the membrane voltage resets. The LIF model describes the dynamic behavior of the neuron as shown in equation (3) and equation (4).

$$C \frac{dV ( t )}{dt} + \frac{V ( t )}{{R}_{leak}} = \sum G \cdot {V}_{r} \qquad ( 3 )$$

$$Spike = \{ \begin{matrix}1 , & V ( t ) \geq {V}_{th} \\ 0 , & V ( t ) < {V}_{th}\end{matrix} \qquad ( 4 )$$

where C is a membrane capacitance, V(t) is a membrane voltage, G and Vᵣ are the synapse strength and the stimulation amplitude, and Rₗₑₐₖ is a leakage resistance. Without continuous stimulation, the membrane voltage will return to a resting state spontaneously through the leakage resistance. The leaky integrate-and-fire model above-mentioned is an embryonic form of the neuron model designed in the present disclosure.

As shown in FIG. 2 to FIG. 3C, according to embodiments of the present disclosure, before the controlling an on-off state of a first switching transistor and a second switching transistor of the neuron circuit in response to the bit line current signal so that the neuron circuit outputs the mono-pulse output signal in response to the on-off state, the method further includes:
controlling an on-off state to satisfy that the first switching transistor is on and the second switching transistor is off, and implementing a pre-charging capacitor voltage of the neuron circuit in response to the on-off state, wherein the on-off state is a transistor on-off state combination formed by the respective on-off states of the first switching transistor S1 and the second switching transistor S2 of the above-mentioned neuron circuit; the first switching transistor S1 and the second switching transistor S2 may be transistor control units with circuit switching function, and the operation process of the neuron circuit may be well implemented through the first switching transistor S1 and the second switching transistor S2.

First, capacitor pre-charging is performed for the capacitor C of the neuron circuit. The first switching transistor is set to S1=ON, while the second switching transistor is set to S2=OFF, so as to implement the pre-charging of the capacitor C, so that the pre-charging capacitor of the capacitor C meets the capacitor voltage V_{c}^{step1}, and the capacitor C stores enough initial electrons to be discharged by the column current corresponding to the negative weight. The expression of the pre-charge voltage V_{c}^{step1} is shown in equation (5):

$${V}_{c}^{step 1} = \frac{{V}_{dd} {R}_{leak} ( 1 - {e}^{- \frac{{R}_{pre} + {R}_{leak}}{{R}_{pre} {R}_{leak} C} \cdot {T}_{pre}} )}{{R}_{pre} + {R}_{leak}} \approx \frac{{V}_{dd}}{{R}_{pre} C} \cdot {T}_{pre} \qquad ( 5 )$$

where Rₚᵣₑ is an equivalent pre-charge resistance, Tₚᵣₑ is pre-charge time, and V_{dd} is a power supply voltage.

As shown in FIG. 2 to FIG. 3C, according to embodiments of the present disclosure, in the controlling an on-off state of a first switching transistor and a second switching transistor of the neuron circuit in response to the bit line current signal so that the neuron circuit outputs the mono-pulse output signal in response to the on-off state, the method includes:
controlling an on-off state to satisfy that the first switching transistor and the second switching transistor are both off, and enabling the neuron circuit to generate a first capacitor voltage according to the bit line current signal and the pre-charging capacitor voltage in response to the on-off state and the bit line current signal; and
controlling an on-off state to satisfy that the first switching transistor is off and the second switching transistor is on, and coding and outputting the first capacitor voltage as the mono-pulse output signal with a discrete delay time.

After the capacitor C of the neuron circuit completes the above-mentioned pre-charging operation, the vector-matrix multiplication calculation process is further performed. The first switching transistor is set to S1=OFF, while the second switching transistor is set to S2=OFF. The coded neural network input vector signal is applied to an algorithm weight conductance (G^{weight}) in the form of the mono-pulse input signal with discrete delay time, while the mono-pulse input signal with the longest delay time is also applied to a weight difference conductance (G^{diff}). The memory array mapped by the weight matrix performs the multiplication and accumulation operation in response to the mono-pulse input signal, so as to generate the bit line current signal.

A contribution Vₘᵤₗ of a response current of a weighted conductance value Gᵢⱼ to the mono-pulse input signal Xᵢ·T_{code} to the capacitor voltage of the neuron circuit is shown in equation (6):

$${V}_{mul} = {V}_{r} {G}_{ij} {R}_{leak} ( 1 - {e}^{- \frac{{T}_{sense}}{{R}_{leak} C}} ) {e}^{- \frac{( {2}^{N} - 1 - {X}_{i} ) {T}_{code}}{{R}_{leak} C}} \qquad ( 6 )$$

Corresponding to the above-mentioned equation (6), the capacitor voltage V_{c}^{step2} represents a sum of the multiplication and accumulation result of the mono-pulse input signal of rows H₁-H_{i+c} and the conductance values of rows H₁-H_{i+c} of the j^{th} column and the j+1^{th} (j is odd) column of the memory array and the contribution Vₘᵤₗ of the response current of the weighted conductance value Gᵢⱼ to the mono-pulse input signal Xᵢ·T_{code} to the capacitor voltage of the neuron circuit, as shown in equation (7):

$${V}_{c}^{step 2} = {R}_{leak} \cdot {\sum }_{i} {V}_{r} ( {{G}_{ij}}^{+} - {G}_{ij}^{-} ) ( 1 - {e}^{- \frac{{T}_{sense}}{{R}_{leak} C}} ) {e}^{- \frac{( {2}^{N} - 1 - {X}_{i} ) {T}_{code}}{{R}_{leak} C}} + {R}_{leak} \cdot {V}_{r} {G}_{j}^{diff} ( 1 - {e}^{- \frac{{T}_{sense}}{{R}_{leak} C}} ) + {V}_{c}^{step 1} {e}^{- \frac{{T}_{sense} + ( {2}^{N} - 1 ) {T}_{code}}{{R}_{leak} C}} \qquad ( 7 )$$

where

$${k}_{leak} = {e}^{- \frac{( {2}^{N} - 1 ) {T}_{code}}{{R}_{leak} C}} ,$$

Vᵣ is a bit line control voltage of the memory array, and kₗₑₐₖ is the leakage coefficient of the LIF neuron model.

Rearranging the capacitor voltage expression of equation (7) to obtain equation (8):

$${V}_{c}^{step 2} = {KR}_{leak} {V}_{r} {\sum }_{i} ( {G}_{ij}^{+} - {G}_{ij}^{-} ) \cdot ( {e}^{\frac{{X}_{i} \cdot {T}_{code}}{{R}_{leak} C}} - 1 ) + {k}_{leak} {k}_{sense} {V}_{c}^{step 1} \qquad ( 8 )$$

$$wherein , {k}_{sense} = {e}^{- \frac{{T}_{sense}}{{R}_{leak} C}} , K = {k}_{leak} ( 1 - {k}_{sense} ) .$$

Further, on the basis of the above-mentioned equation (8), the operation of encoding the vector-matrix multiplication result involves that the first switching transistor is set to S1=OFF, while the second switching transistor is set to S2=ON. At this point, the capacitor C discharges through the constant current source CS (its current is Iₜᵣₐₙ) and the leakage resistor Rₗₑₐₖ, and codes the capacitor voltage representing the vector-matrix multiplication result into a mono-pulse signal with discrete delay time. In this process, a relationship between the capacitor voltage V_{c}^{step3} and the discharge time Tout is shown in equation (9) below:

$${V}_{c}^{step 3} = - {I}_{tran} {R}_{leak} ( 1 - {e}^{- \frac{{T}_{out}}{{R}_{leak} C}} ) + {V}_{c}^{step 2} {e}^{- \frac{{T}_{out}}{{R}_{leak} C}} \qquad ( 9 )$$

When the capacitor voltage V_{c}^{step3} is less than the threshold voltage Vₜₕ and the rising edge of clock is reached, the neuron circuit 300 will trigger an output pulse, as shown in equation (10):

$$Spike = \{ \begin{matrix}1 , & {V}_{c}^{step 3} ( {T}_{out} ) < {V}_{th} \\ 0 , & {V}_{c}^{step 3} ( {T}_{out} ) \geq {V}_{th}\end{matrix} \qquad ( 10 )$$

Therefore, when the threshold voltage is set to Vₜₕ=kₗₑₐₖ·kₛₑₙₛₑ·V_{c}^{step1}, a voltage variation Vᵥₘₘ caused in the discharge process is shown in equation (11) below:

$${V}_{vmm} = {V}_{c}^{step 2} - {V}_{th} = {KR}_{leak} {V}_{r} {\sum }_{i} ( {G}_{ij}^{+} - {G}_{ij}^{-} ) \cdot ( {e}^{\frac{{X}_{i} \cdot {T}_{code}}{{R}_{leak} C}} - 1 ) \qquad ( 11 )$$

When (2^{N}−1) T_{code}<<Rₗₑₐₖ·C is satisfied, the leakage process of the capacitor C may be equivalent to a linear process, that is, equation (11) may be approximated to equation (12) below.

$${V}_{vmm} \approx \frac{{KV}_{r}}{C} {\sum }_{i} ( {{G}_{ij}}^{+} - {G}_{ij}^{-} ) \cdot {X}_{i} \cdot {T}_{code} \qquad ( 12 )$$

The voltage difference Vᵥₘₘ may approximately represent the vector-matrix multiplication result.

Therefore, the discharge time Tout required for the capacitor voltage to change Vᵥₘₘ in the neuron circuit 300 is shown in equation (13) below.

$${T}_{out} = {R}_{leak} C \cdot ln ( \frac{{KR}_{leak} {V}_{r} {\sum }_{i} ( {G}_{ij}^{+} - {G}_{ij}^{-} ) \cdot ( {e}^{\frac{{X}_{i} \cdot {T}_{code}}{{R}_{leak} C}} - 1 )}{{k}_{leak} {k}_{sense} {V}_{c}^{step 1} + {I}_{tran} {R}_{leak}} + 1 ) \qquad ( 13 )$$

When (2^{N}−1) T_{code}<<Rₗₑₐₖ·C is satisfied, the above-mentioned equation (13) may be approximated to equation (14) below:

$$\begin{matrix}{T}_{out} \approx \frac{{KR}_{leak} {V}_{r}}{{k}_{leak} {k}_{sense} {V}_{c}^{step 1} + {I}_{tran} {R}_{leak}} {\sum }_{i} ( {{G}_{ij}}^{+} - {G}_{ij}^{-} ) \cdot {X}_{i} \cdot {T}_{code} \\ \approx \frac{{R}_{leak}}{{k}_{leak} {k}_{sense} {V}_{c}^{step 1} + {I}_{tran} {R}_{leak}} \cdot {V}_{vmm}\end{matrix} \qquad ( 14 )$$

Therefore, the vector-matrix multiplication result Vᵥₘₘ is encoded as the delay time Tout of the mono-pulse input signal.

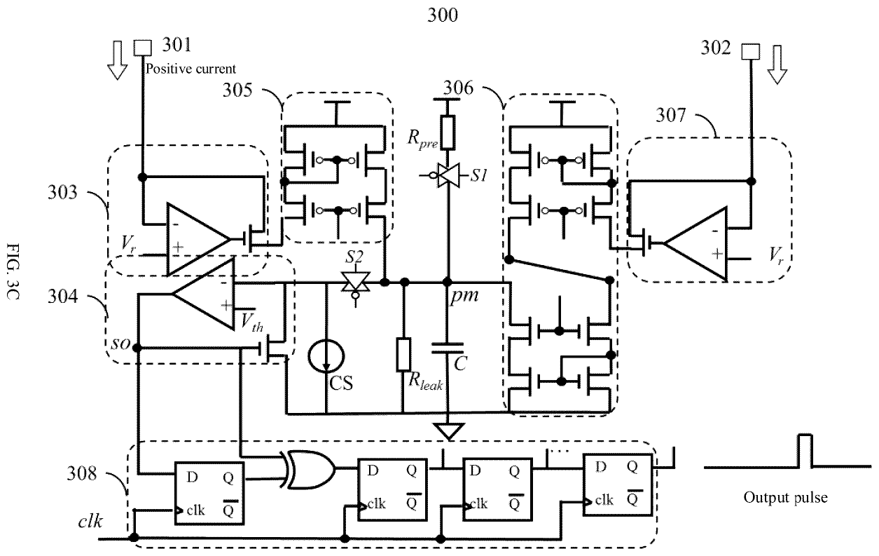

As shown in FIG. 4A and FIG. 4B, Hspice tools and the like may be used to simulate the above-mentioned neural network in-memory computing implementation mode based on discrete time coding. The input and weight are from a convolutional neural network that recognizes a handwritten digit data set. FIG. 4A shows node waveform diagrams of a capacitor voltage V(pm) of a node pm and a voltage V(so) of a node so of the comparator 304 in the neuron circuit, respectively, where the node pm and the node so are shown in FIG. 3C. During the operation of pre-charging the capacitor, the capacitor voltage is pre-charged to 1.4 V. In a process of vector-matrix multiplication calculation processing, the capacitor voltage is determined by the charge and discharge current of the array and the leakage current of the neuron. At a preceding time, the charge current from the weight array is greater than the leakage current of the neuron, and at a later time, the charge current from the weight array is gradually less than the leakage current of the neuron. Therefore, in the process of vector-matrix multiplication calculation processing, the capacitor voltage first increases and then decreases. Further, during the encoding operation of vector-matrix multiplication result, the constant current source CS and the leakage resistor Rₗₑₐₖ discharge the capacitor simultaneously. When the capacitor voltage drops to the threshold voltage, the comparator 304 triggers an output pulse.

As shown in FIG. 4B, the relationship between the discrete delay time Tout of the output pulse (i.e., the mono-pulse output signal) and the target vector-matrix multiplication result ΣG·X·T_{code} is obtained through the simulation. Specifically, 50 groups of weights and input sets are randomly selected from the convolutional neural network which recognizes the handwritten digit data set, and the target vector-matrix multiplication results ΣG·X·T_{code} are obtained respectively. Then, Hspice tools and other tools are used to simulate the delay time Tout of the output pulse of the neural circuit. The simulation results show that the pulse delay time Tout may proximately represent the results of vector-matrix multiplication, which shows an excellent simulation effect.

Therefore, the above-mentioned methods of embodiments of the present disclosure may greatly reduce the number of input pulses through the implementation method for neural network in-memory calculation based on discrete time coding, thus greatly reducing the dynamic power consumption of memory arrays including the NVM array and corresponding neural circuits. The implementation method for neural network in-memory calculation based on discrete time coding may be flexibly applied to a multi-layer perceptron and convolutional neural network based on time coding obtained by direct training or conversion. Therefore, the above-mentioned methods of embodiments of the present disclosure propose an implementation solution of a neural network in-memory computing based on discrete time coding, which has high energy efficiency and may be applied to a large-scale neural network.

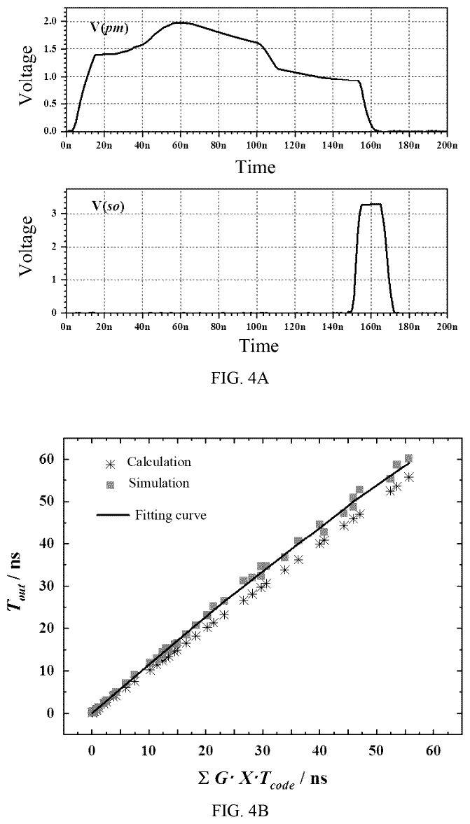

Based on the above-mentioned operating method for an in-memory computing architecture applied to a neural network, the present disclosure further provides an apparatus for operating an in-memory computing architecture applied to a neural network. The apparatus will be described in detail below with reference to FIG. 5.

FIG. 5 schematically shows a block diagram of an apparatus for operating an in-memory computing architecture applied to a neural network according to an embodiment of the present disclosure.

As shown in FIG. 5, an apparatus 500 of operating an in-memory computing architecture applied to a neural network in the embodiment includes an input signal generation module 510, a bit line signal generation module 520, and a control output module 530.

The input signal generation module 510 is used to generate a mono-pulse input signal based on discrete time coding. In an embodiment, the input signal generation module 510 may be used to perform the operation S201 described above, which will not be repeated here.

The bit line signal generation module 520 is used to input the mono-pulse input signal into a memory array of the in-memory computing architecture to generate a bit line current signal corresponding to the memory array. In an embodiment, the bit line signal generation module 520 may be used to perform the operation S202 described above, which will not be repeated here.

The control output module 530 is used to control a neuron circuit of the in-memory computing architecture to output a mono-pulse output signal based on discrete time coding according to the bit line current signal, and the mono-pulse output signal is used as a mono-pulse input signal of a memory array of a next layer of neural network in a next in-memory computing cycle. In an embodiment, the control output module 530 may be used to perform the operation S203 described above, which will not be repeated here.

According to embodiments of the present disclosure, any number of modules of the input signal generation module 510, the bit line signal generation module 520 and the control output module 530 may be combined in one module for implementation, or any one of the modules may be divided into a plurality of modules. Alternatively, at least some functions of one or more of the modules may be combined with at least some functions of other modules and implemented in one module. According to embodiments of the present disclosure, at least one of the input signal generation module 510, the bit line signal generation module 520 and the control output module 530 may be implemented at least partially as a hardware circuit, such as a field programmable gate array (FPGA), a programmable logic array (PLA), a system on a chip, a system on a substrate, a system on a package, and an application specific integrated circuit (ASIC), or may be implemented by any other reasonable means of hardware or firmware that integrates or packages a circuit, or may be implemented in any one of or a suitable combination of three implementation methods of software, hardware, and firmware. Alternatively, at least one of the input signal generation module 510, the bit line signal generation module 520, and the control output module 530 may be implemented at least partially as a computer program module, which when executed, may perform a corresponding function.

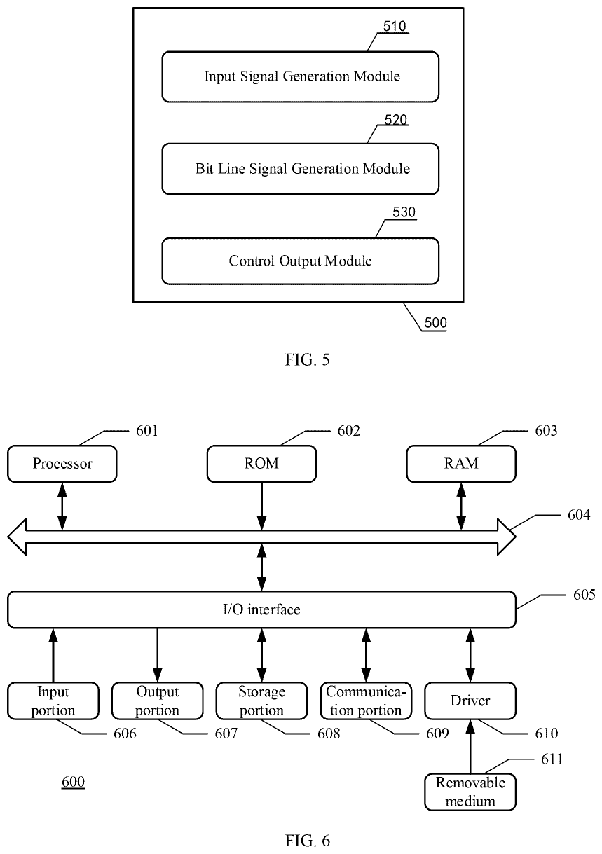

FIG. 6 schematically shows a block diagram of an electronic device suitable for implementing a method for operating an in-memory computing architecture applied to a neural network according to an embodiment of the present disclosure.

As shown in FIG. 6, the electronic device 600 according to embodiments of the present disclosure includes a processor 601 that may perform various appropriate actions and processes according to programs stored in a read-only memory (ROM) 602 or programs loaded from the storage portion 608 into a random access memory (RAM) 603. The processor 601 may include, for example, a general-purpose microprocessor (e.g., a CPU), an instruction set processor and/or a related chipset and/or a special-purpose microprocessor (e.g., an application-specific integrated circuit (ASIC)), etc. The processor 601 may also include an on-board memory for caching purposes. The processor 601 may include a single processing unit or a plurality of processing units for performing different actions of a method flow according to embodiments of the present disclosure.

In the RAM 603, various programs and data required for the operation of the electronic device 600 are stored. The processor 601, the ROM 602 and the RAM 603 are connected to each other through a bus 604. The processor 601 performs various operations of the method flow according to embodiments of the present disclosure by executing the programs in the ROM 602 and/or the RAM 603. It should be noted that the programs may also be stored in one or more memories other than the ROM 602 and the RAM 603. The processor 601 may also perform various operations of the method flow according to embodiments of the present disclosure by executing the programs stored in the one or more memories.

According to embodiments of the present disclosure, the electronic device 600 may also include an input/output (I/O) interface 605, and the input/output (I/O) interface 605 is also connected to the bus 604. The electronic device 600 may also include one or more of the following components connected to the I/O interface 605: an input portion 606 including a keyboard, a mouse, etc.; an output portion 607 including a cathode ray tube (CRT), a liquid crystal display (LCD), etc., and a speaker, etc.; a storage portion 608 including a hard disk, etc.; and a communication portion 609 including a network interface card such as a LAN card, a modem, etc. The communication portion 609 performs communication processing via a network such as the Internet. A drive 610 is also connected to the I/O interface 605 as needed. A removable medium 611, such as a magnetic disk, an optical disk, a magneto-optical disk, a semiconductor memory, etc., is mounted on the drive 610 as needed so that a computer program read therefrom is installed into the storage portion 605 as needed.

The present disclosure further provides a computer-readable medium. The computer-readable medium may be included in the device/apparatus/system described in the above-mentioned embodiments, and may also exist alone without being assembled into the device/apparatus/system. The computer-readable medium described above carries one or more programs, and when the one or more programs are executed, the method according to embodiments of the present disclosure may be implemented.

According to embodiments of the present disclosure, the computer-readable storage medium may be a nonvolatile computer-readable storage medium. The computer-readable storage medium may include, for example, but is not limited to, a portable computer disk, a hard disk, a random access memory (RAM), a read only memory (ROM), an erasable programmable read only memory (EPROM or flash memory), a portable compact disk read only memory (CD-ROM), an optical storage device, a magnetic storage device, or any suitable combination of the above. In the present disclosure, the computer-readable storage medium may be any tangible medium that contains or stores a program that may be used by or in conjunction with an instruction execution system, apparatus, or device. For example, according to embodiments of the present disclosure, the computer-readable storage medium may include the ROM 602 and/or the RAM 603 described above and/or one or more memories other than the ROM 602 and the RAM 603.

Embodiments of the present disclosure further include a computer program product including a computer program, and the computer program contains program code for performing the method illustrated in the flowchart. When the computer program product runs in the computer system, the program code is used to enable the computer system to implement the method provided in embodiments of the present disclosure.

The computer program, when executed by the processor 601, performs the functions described above defined in the system/apparatus of embodiments of the present disclosure. According to embodiments of the present disclosure, the system, apparatus, module, unit, etc. described above may be implemented by the computer program module.

In one embodiment, the computer program may be hosted on a tangible storage medium such as an optical storage device, a magnetic storage device, and the like. In another embodiment, the computer program may also be transmitted and distributed in the form of signals on the network medium, downloaded via the communication portion 609 and installed, and/or installed from the removable medium 611. The program code contained in the computer program may be transmitted by any appropriate network medium, including but not limited to: wireless, wired, etc., or any suitable combination of the above.

In such an embodiment, the computer program may be downloaded from the network via the communication portion 609 and installed, and/or installed from the removable medium 611. The computer program, when executed by the processor 601, performs the functions described above defined in the system of embodiments of the present disclosure. According to embodiments of the present disclosure, the system, device, apparatus, module, unit, etc. described above may be implemented by the computer program module.

According to embodiments of the present disclosure, program codes for implementing the computer programs provided by embodiments of the present disclosure may be written in one programming language or any combination of more programming languages. Specifically, the computing programs may be implemented using advanced procedure-oriented and/or object-oriented programming languages, and/or assembler/machine languages. Programming languages include but are not limited to Java, C++, Python, “C” or similar programming languages. The program codes may be executed entirely on a user computing device, partially on a user device and partially on a remote computing device, or entirely on a remote computing device or server In situations involving the remote computing device, the remote computing device may be connected to the user computing device through any kind of network, including a local area network (LAN) or a wide area network (WAN), or the user computing device may be connected to an external computing device (for example, using an Internet service provider to connect via the Internet).

The flowcharts and block diagrams in the drawings illustrate the architecture, functionality, and operation of possible implementations of systems, methods and computer program products according to various embodiments of the present disclosure. In this regard, each block in the flowcharts or block diagrams may represent a module, program segment, or portion of code, which contains one or more executable instructions for implementing the specified logical function. It should also be noted that, in some alternative implementations, the functions noted in the blocks may occur out of the order noted in the drawings. For example, two blocks shown in succession may, in fact, be executed substantially concurrently, or the two blocks may sometimes be executed in a reverse order, depending upon the functionality involved. It should also be noted that each block of the block diagrams or flowcharts, and combinations of the blocks in the block diagrams or flowcharts, may be implemented by using a special purpose hardware-based system that performs the specified functions or operations, or may be implemented using a combination of a special purpose hardware and computer instructions.

Those skilled in the art will appreciate that features recited in the various embodiments of the present disclosure and/or the claims may be combined and/or incorporated in a variety of ways, even if such combinations or incorporations are not clearly recited in the present disclosure. In particular, the features recited in the various embodiments of the present disclosure and/or the claims may be combined and/or incorporated in a variety of ways without departing from the spirit and teachings of the present disclosure, and all such combinations and/or incorporations fall within the scope of the present disclosure.

Thus far, embodiments of the present disclosure have been described in detail with reference to the accompanying drawings.

Embodiments of the present disclosure have been described above. However, these embodiments are for illustrative purposes only, and are not intended to limit the scope of the present disclosure. Although the various embodiments are described above separately, this does not mean that the measures in the various embodiments may not be advantageously used in combination. The scope of the present disclosure is defined by the appended claims and their equivalents. Without departing from the scope of the present disclosure, those skilled in the art may make various substitutions and modifications, and these substitutions and modifications should all fall within the scope of the present disclosure.

1. A method for operating an in-memory computing architecture applied to a neural network, comprising:
generating a mono-pulse input signal based on discrete time coding;
inputting the mono-pulse input signal into a memory array of the in-memory computing architecture to generate a bit line current signal corresponding to the memory array; and
controlling a neuron circuit of the in-memory computing architecture to output a mono-pulse output signal based on discrete time coding according to the bit line current signal, wherein the mono-pulse output signal is configured as a mono-pulse input signal of a memory array of the next layer of neural network in the next in-memory computing cycle.

2. The method according to claim 1, wherein generating a mono-pulse signal based on discrete time coding comprises:
quantizing neural network input vector signal and generating a corresponding quantized input signal; and
coding the quantized input signal according to a preset discrete delay time coding rule to generate the mono-pulse input signal based on discrete time coding,
wherein the preset discrete delay time coding rule is a rule for coding quantized input of neural networks into the mono-pulse input signal according to a delay time between a start time of an enable signal corresponding to the in-memory computing cycle and an arrival time of the mono-pulse input signal, wherein a length of the delay time is the size of the quantized input signal.

3. The method according to claim 1, wherein before inputting the mono-pulse input signal into a memory array of the in-memory computing architecture to generate a bit line current signal corresponding to the memory array, the method further comprises:
mapping a weight matrix corresponding to neural network input vector signal to each memory unit of the memory array, comprising:
mapping the weight matrix to conductance values in two adjacent columns of the memory array representing positive and negative respectively according to the symbol of weights; and
mapping a weight difference between two adjacent columns to conductance values of two adjacent columns representing positive and negative respectively of the memory array according to a symbol of a weight difference, wherein the weight difference is a difference between a sum of weights of an adjacent negative column and a sum of weights of an adjacent positive column.

4. The method according to claim 3, wherein inputting the mono-pulse input signal into a memory array of the in-memory computing architecture to generate a bit line current signal corresponding to the memory array comprises:
inputting the mono-pulse input signal into the memory array of the in-memory computing architecture; and
controlling the memory array to complete matrix-vector multiplication based on the input mono-pulse input signal, to generate the bit line current signal.

5. The method according to claim 1, wherein the controlling a neuron circuit of the in-memory computing architecture to output a mono-pulse output signal based on discrete time coding according to the bit line current signal comprises:
controlling an on-off state of a first switching transistor and a second switching transistor of the neuron circuit in response to the bit line current signal, so that the neuron circuit outputs the mono-pulse output signal in response to the on-off state.

6. The method according to claim 5, wherein before the controlling an on-off state of a first switching transistor and a second switching transistor of the neuron circuit in response to the bit line current signal so that the neuron circuit outputs the mono-pulse output signal in response to the on-off state, the method further comprises:
controlling an on-off state to satisfy that the first switching transistor is on and the second switching transistor is off, and implementing a pre-charging capacitor voltage of the neuron circuit in response to the on-off state.

7. The method according to claim 6, wherein the controlling an on-off state of a first switching transistor and a second switching transistor of the neuron circuit in response to the bit line current signal so that the neuron circuit outputs the mono-pulse output signal in response to the on-off state comprises:
controlling an on-off state to satisfy that the first switching transistor and the second switching transistor are both off, and enabling the neuron circuit to generate a first capacitor voltage according to the bit line current signal and the pre-charging capacitor voltage in response to the on-off state and the bit line current signal; and
controlling an on-off state to satisfy that the first switching transistor is off and the second switching transistor is on, and coding and outputting the first capacitor voltage as the mono-pulse output signal with a discrete delay time.

8. An apparatus for operating an in-memory computing architecture applied to a neural network, comprising:
an input signal generation module configured to generate a mono-pulse input signal based on discrete time coding;
a bit line signal generation module configured to input the mono-pulse input signal into a memory array of the in-memory computing architecture to generate a bit line current signal corresponding to the memory array; and
a control output module configured to control a neuron circuit of the in-memory computing architecture to output a mono-pulse output signal based on discrete time coding according to the bit line current signal, wherein the mono-pulse output signal is configured as a mono-pulse input signal of a memory array of a next layer of neural network in a next in-memory computing cycle.

9. An electronic device, comprising:
one or more processors; and
a storage apparatus for storing one or more programs,
wherein one or more programs, when executed by one or more processors, cause one or more processors to implement the method according to claim 1.

10. An electronic device, comprising:
one or more processors; and
a storage apparatus for storing one or more programs,
wherein one or more programs, when executed by one or more processors, cause one or more processors to implement the method according to claim 2.

11. An electronic device, comprising:
one or more processors; and
a storage apparatus for storing one or more programs,
wherein one or more programs, when executed by one or more processors, cause one or more processors to implement the method according to claim 3.

12. An electronic device, comprising:
one or more processors; and
a storage apparatus for storing one or more programs,
wherein one or more programs, when executed by one or more processors, cause one or more processors to implement the method according to claim 4.

13. An electronic device, comprising:
one or more processors; and
a storage apparatus for storing one or more programs,
wherein one or more programs, when executed by one or more processors, cause one or more processors to implement the method according to claim 5.

14. An electronic device, comprising:
one or more processors; and
a storage apparatus for storing one or more programs,
wherein one or more programs, when executed by one or more processors, cause one or more processors to implement the method according to claim 6.

15. An electronic device, comprising:
one or more processors; and
a storage apparatus for storing one or more programs,
wherein one or more programs, when executed by one or more processors, cause one or more processors to implement the method according to claim 7.
